(19) United States
(12) Patent Application Publication
(10) Pub. No.: US 2025/0311552 A1
(43) Pub. Date: Oct. 2, 2025

(54) DISPLAY PANEL, METHOD OF MANUFACTURING DISPLAY PANEL, AND ELECTRONIC DEVICE

(71) Applicants: Hefei Visionox Technology Co., Ltd., Hefei (CN); Visionox Technology Inc., Suzhou (CN)

(72) Inventors: Liusong NI, Hefei (CN); Yuan YAO, Hefei (CN); Bowen YANG, Hefei (CN); Murong XUE, Hefei (CN); Tianwei ZHAI, Hefei (CN); Zhenhai YUE, Hefei (CN); Chen XU, Hefei (CN); Xiujian ZHU, Hefei (CN)

(73) Assignees: Hefei Visionox Technology Co., Ltd., Hefei (CN); Visionox Technology Inc., Suzhou (CN)

(21) Appl. No.: 18/779,800

(22) Filed: Jul. 22, 2024

(30) Foreign Application Priority Data
Mar. 29, 2024 (CN) 202410373960.6

(51) Int. Cl. H10K 59/122; H10K 59/12; H10K 59/131

(52) U.S. Cl. CPC H10K 59/122; H10K 59/1201; H10K 59/131

(57) ABSTRACT

A display panel, a method for manufacturing a display panel, and an electronic device, and the display panel includes: a substrate; a wiring layer located on a side of the substrate, here, the wiring layer includes a first wiring; an organic layer located on a side of the wiring layer away from the substrate, here, the organic layer includes a contact hole exposing at least a part of the first wiring; and a pixel definition layer located on a side of the organic layer away from the substrate, here, the pixel definition layer extends into the contact hole and covers a side of the organic layer facing the contact hole, and a part of the pixel definition layer located within the contact hole exposes at least a part of the first wiring.

### CROSS REFERENCE TO RELATED APPLICATION

The present application claims priority to Chinese Patent Application No. 202410373960.6 filed on Mar. 29, 2024, and titled “DISPLAY PANEL, METHOD FOR MANUFACTURING DISPLAY PANEL, AND ELECTRONIC DEVICE”, which is incorporated herein by reference in its entirety.

### TECHNICAL FIELD

The present application relates to the field of display, and particularly to a display panel, a method for manufacturing a display panel, and an electronic device.

### BACKGROUND

With the continuous development of display technology, display panels are more and more widely applied, and user's demand for the display panels are greater and greater. However, the quality of existing display panels needs be improved.

### SUMMARY

In order to overcome the above deficiency in the prior art, the purpose of the present application is to provide a display panel including: a substrate; a wiring layer located on a side of the substrate, wherein the wiring layer includes a first wiring; an organic layer located on a side of the wiring layer away from the substrate, wherein the organic layer includes a contact hole exposing at least a part of the first wiring; and a pixel definition layer located on a side of the organic layer away from the substrate, wherein the pixel definition layer extends into the contact hole and covers a side of the organic layer facing the contact hole, and a part of the pixel definition layer is located within the contact hole and at least a part of the first wiring is exposed in the contact hole.

In some possible implementations, a material of the pixel definition layer includes an inorganic material.

In some possible implementations, the display panel further includes an isolation structure located on a side of the organic layer away from the substrate, and the isolation structure extends into the contact hole to be in contact with the first wiring.

In some possible implementations, the display panel includes a display region, at least a part of the pixel definition layer located in the display region defines a pixel opening, the isolation structure is provided on a side of the pixel definition layer away from the substrate, at least a part of the isolation structure located in the display region defines an isolation opening, and an orthographic projection of the pixel opening on the substrate is located within an orthographic projection of the isolation opening on the substrate.

In some possible implementations, the organic layer includes a planarization layer;

preferably, the display region of the display panel further includes: a first electrode located on a side of the planarization layer away from the substrate, here, at least a part of the first electrode is located within the pixel opening; a light-emitting unit at least partially located within the pixel opening and located on a side of the first electrode away from the substrate, here the light-emitting unit is in contact with the first electrode; and a second electrode at least partially located within the pixel opening and located on a side of the light-emitting unit away from the substrate, here the second electrode is in contact with the light-emitting unit.

In some possible implementations, the second electrode is in contact with the isolation structure. The present application further provides a display panel including: a substrate; a wiring layer located on a side of the substrate, wherein the wiring layer includes a first wiring; an organic layer located on a side of the wiring layer away from the substrate, wherein the organic layer includes a contact hole exposing at least a part of the first wiring; and a first material layer covering a side of the organic layer facing the contact hole and exposing the first wiring; here water absorbability of the first material layer is lower than water absorbability of the organic layer; and an auxiliary electrode located on a side of the first material layer away from the substrate and extending into the contact hole to be in contact with the first wiring.

In some possible implementations, the display panel includes a display region and a contact region located on a side of the display region, and the contact hole is located in the contact region.

In some possible implementations, a material of the first material layer includes an inorganic material.

In some possible implementations, the display panel further includes a pixel definition layer located on a side of the organic layer away from the substrate, and the first material layer is provided in the same layer as the pixel definition layer.

In some possible implementations, the first material layer and the pixel definition layer are formed as an integrated structure.

In some possible implementations, the display panel further includes an isolation structure and a light-emitting unit, and the isolation structure is located on a side of the first material layer away from the substrate and is provided with an isolation opening; the light-emitting unit is located in the isolation opening; and the isolation structure is reused as the auxiliary electrode.

In some possible implementations, the isolation structure includes a first layer, a second layer, and a third layer stacked along a direction away from the substrate; or the isolation structure includes a second layer and a third layer stacked along a direction away from the substrate.

In some possible implementations, a material of the second layer includes aluminum, and a material of the third layer includes titanium;

preferably, a material of the first layer includes molybdenum.

The present application further provides a method for manufacturing a display panel, and the method includes: providing a substrate; providing a wiring layer on a side of the substrate, wherein the wiring layer includes a first wiring; providing an organic layer on a side of the wiring layer away from the substrate, and etching the organic layer to form a contact hole exposing at least a part of the first wiring; and providing a pixel definition layer on a side of the organic layer away from the substrate, here the pixel definition layer extends into the contact hole and covers a side of the organic layer facing the contact hole, and exposing at least a part of the first wiring within the contact hole.

In some possible implementations, the wiring layer further includes a second wiring; and forming the contact hole on the organic layer includes: etching the organic layer to form an electrode connection hole exposing at least a part of the second wiring and the contact hole exposing at least a part of the first wiring; preferably, before providing the pixel definition layer on the side of the organic layer away from the substrate, the method further includes: forming a first electrode on a side of the organic layer away from the substrate, here the first electrode extends into the electrode connection hole to be electrically connected to the second wiring.

In some possible implementations, after providing the pixel definition layer on the side of the organic layer away from the substrate, the method further includes: providing an isolation structure on a side of the organic layer away from the substrate, wherein the isolation structure extends into the contact hole to be in contact with the first wiring. The present application further provides a method for manufacturing a display panel, and the method includes: providing a substrate; providing a wiring layer on a side of the substrate, wherein the wiring layer includes a first wiring; providing an organic layer on a side of the wiring layer away from the substrate, and etching the organic layer to form a contact hole exposing at least a part of the first wiring; providing a first material layer on a side of the organic layer away from the substrate, wherein the first material layer covers a side of the organic layer facing the contact hole and exposes the first wiring; and water absorbability of the first material layer is lower than water absorbability of the organic layer; and providing an auxiliary electrode on a side of the first material layer away from the substrate, wherein the auxiliary electrode extends into the contact hole to be in contact with the first wiring.

In some possible implementations, providing the auxiliary electrode on the side of the first material layer away from the substrate includes: providing an isolation structure on a side of the first material layer away from the substrate; wherein the isolation structure includes an isolation opening and is reused as the auxiliary electrode.

Another purpose of the present application is to provide an electronic device including the display panel according to the present application.

With respect to the prior art, the present application has the following beneficial effects:

The present application provides the display panel, the method for manufacturing the display panel, and the electronic device. In the display panel having the isolation structure, the pixel definition layer in the contact hole covers a side surface of the organic layer facing the contact hole, and the organic layer is prevented from being exposed at the contact hole, so that the risk of the organic layer being invaded by water vapor at the contact hole can be reduced, and the yield of subsequent film layer manufacturing can be ensured.

### BRIEF DESCRIPTION OF THE DRAWINGS

The drawings required to describe embodiments of the present application are introduced briefly below to illustrate technical solutions of the embodiments of the present application more clearly. It should be understood that the drawings described below only show some embodiments of the present application, and thus should not be regarded as a limitation of the scope. For those ordinary skilled in the art, other related drawings may be obtained from these drawings without any creative work.

FIG. 1 is a first schematic cross-sectional view of a display panel in the prior art;

FIG. 2 is a second schematic cross-sectional view of a display panel in the prior art;

FIG. 3 is a first schematic cross-sectional view of a display panel according to an embodiment of the present application;

FIG. 4 is a second schematic cross-sectional view of a display panel according to an embodiment of the present application;

FIG. 5 is a regional schematic view of a display panel according to an embodiment of the present application;

FIG. 6 is a third schematic cross-sectional view of a display panel according to an embodiment of the present application;

FIG. 7 is a first schematic view of an isolation structure according to an embodiment of the present application;

FIG. 8 is a fourth schematic cross-sectional view of a display panel according to an embodiment of the present application;

FIG. 9 is a fifth schematic cross-sectional view of a display panel according to an embodiment of the present application;

FIG. 10 is a sixth schematic cross-sectional view of a display panel according to an embodiment of the present application;

FIG. 11 is a seventh schematic cross-sectional view of a display panel according to an embodiment of the present application;

FIG. 12 is a second schematic view of an isolation structure according to an embodiment of the present application;

FIG. 13 is an eighth schematic cross-sectional view of a display panel according to an embodiment of the present application;

FIG. 14 is a ninth schematic cross-sectional view of a display panel according to an embodiment of the present application;

FIG. 15 is a first schematic flowchart of steps of a method for manufacturing a display panel according to an embodiment of the present application;

FIG. 16 is a second schematic flowchart of steps of a method for manufacturing a display panel according to an embodiment of the present application.

### DETAILED DESCRIPTION

In order to make purposes, technical solutions and advantages of the embodiments of the present application clearer, the technical solutions in the embodiments of the present application will be described clearly and completely in conjunction with the accompanying drawings for the embodiments of the present application. Obviously, the described embodiments are merely a part of and not all of the embodiments of the present application. The components in the embodiments of the present application generally described and shown in the accompanying drawings herein can be arranged and designed in various different configurations.

Therefore, the following detailed description of the embodiments of the present application provided in the drawings is not intended to limit the scope of the claimed application, but merely represents the selected embodiments of the present application. Based on the embodiments in the present application, all other embodiments obtained by those ordinary skilled in the art without any creative work shall fall within the protection scope of the present application.

It should be noted that similar reference numbers and letters indicate similar items in the following drawings. Therefore, once a certain item is defined in one drawing, it does not need to be further defined and explained in the subsequent drawings.

In the description of the present application, it is to be illustrated that terms “center”, “upper”, “lower”, “vertical”, “horizontal”, “inner”, “outer”, and the like indicate orientations or positional relationships based on the orientations or the positional relationships shown in the drawings or where the inventive product is placed commonly when in use, which are merely to facilitate and simplify the description of the present application, rather than to indicate or imply that the referenced apparatuses or elements must have a particular orientation, or be constructed and operated in a particular orientation. Accordingly, no limitations are intended to the present application. In addition, the terms “first”, “second”, “third” and the like are only used for distinguishing descriptions, and cannot be understood as indicating or implying relative importance.

It is to be illustrated that different features in the embodiments of the present application can be combined with each other without conflict.

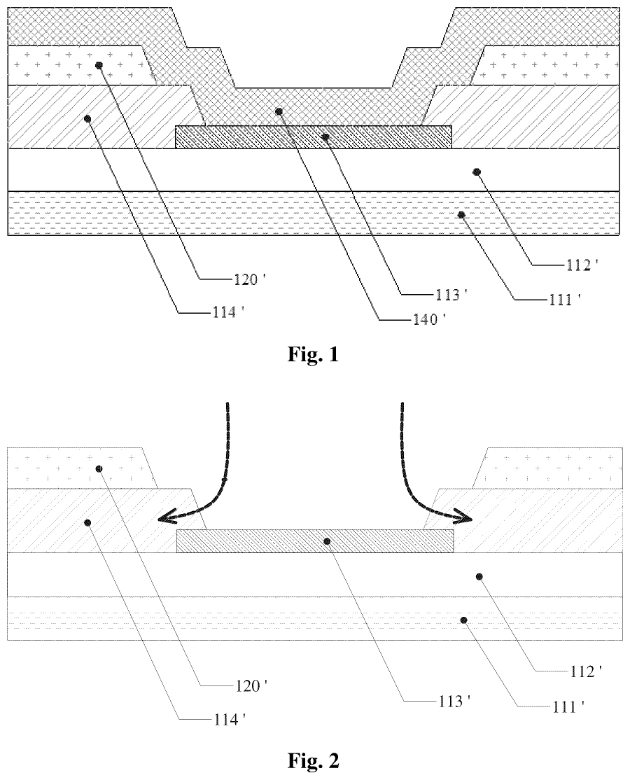

Referring to FIG. 1, some existing display panels using an isolation structure 140 typically include a substrate 111′, a plurality of array functional film layers 112′ located on a side of the substrate 111′, a wiring layer 113′ located on a side of the array functional film layer 112′ away from the substrate 111′, a planarization layer 114′ located on a side of the wiring layer 113′ away from the substrate 111′, a pixel definition layer 120′ located on a side of the planarization layer 114′ away from the substrate 111′, and an isolation structure 140′ located on a side of the pixel definition layer 120′ away from the substrate 111′. Here, the isolation structure 140′ extends and is electrically connected to the wiring layer 113′ through a contact hole 901, 902 penetrating through the pixel definition layer 120′ and the planarization layer 114′.

Under this condition, referring to FIG. 2, in a manufacturing process of the display panel, at the contact hole 901, 902, a part of a location where the planarization layer 114′ is located is not covered by the pixel definition layer 120′, so that the planarization layer 114′ formed by an organic material is easily intruded by the water vapor at this location, and the water vapor released in the subsequent manufacturing process will affect a forming effect of other film layers.

In view of this, the embodiment of the present application provides a solution for reducing the water vapor intrusion during the manufacturing process of the display panel, and the solution provided in the embodiment of the present application is described in detail below.

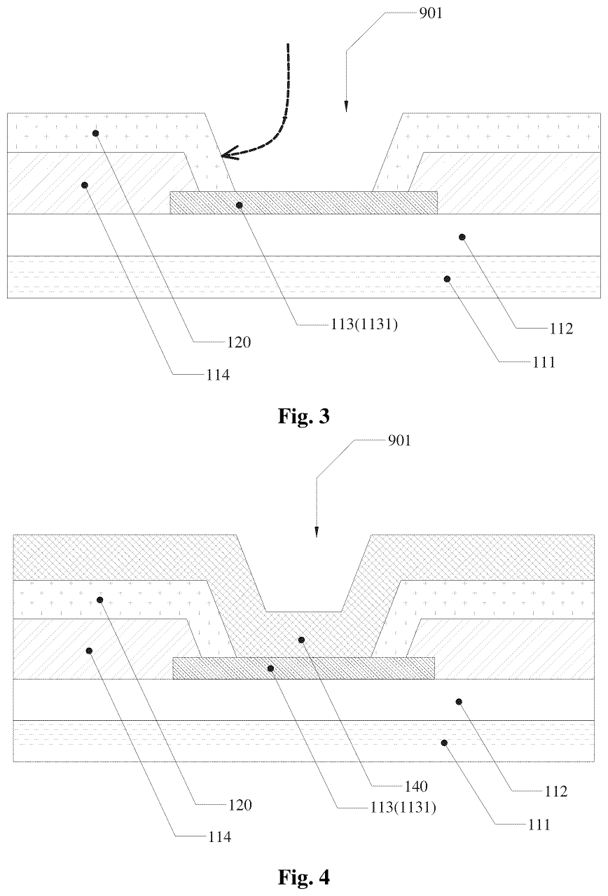

Referring to FIG. 3, FIG. 3 is a schematic view of the display panel according to the embodiment of the present application, and the display panel may include a substrate 111, a wiring layer 113, an organic layer 114, and a pixel definition layer 120.

In the embodiment of the present application, a first wiring layer 113 is located on a side of the substrate 111, and one or more array functional film layers 112 may be included between the first wiring layer 113 and the substrate 111, for example, a buffer layer, a semiconductor layer, one or more other wiring layers 113, and one or more insulation layers may be included.

The wiring layer 113 includes a first wiring 1131. In addition to the first wiring 1131, the wiring layer 113 may further include other wirings, which is not repeated in the embodiment of the present application.

The organic layer 114 is located on a side of the wiring layer 113 away from the substrate 111 and includes a contact hole 901, 902 exposing at least a part of the first wiring 1131. Optionally, in the embodiment of the present application, the organic layer 114 has certain fluidity during the manufacturing process.

The pixel definition layer 120 is located on a side of the organic layer 114 away from the substrate 111 and extends into the contact hole 901, 902 and covers a side of the organic layer 114 facing the contact hole 901, 902, and a part of the pixel definition layer 120 is located within the contact hole and at least a part of the first wiring 1131 is exposed in the contact hole 901, 902. That is, at the contact hole, the pixel definition layer 120 may cover an exposed part of the organic layer 114, and may still expose the first wiring 1131.

Based on the above design, in the embodiment of the present application, the pixel definition layer 120 in the contact hole 901, 902 covers a side surface of the organic layer 114 facing the contact hole 901, 902, and the organic layer 114 is prevented from being exposed at the contact hole 901, 902, so that a risk of the organic layer 114 being invaded by the water vapor at the contact hole 901, 902 can be reduced, and the yield of subsequent film layer manufacturing can be ensured.

In some possible implementations, a material of pixel definition layer 120 includes an inorganic material. In this way, the pixel definition layer 120 provides a better water vapor isolation effect and better protect the organic layer 114 from the water vapor intrusion.

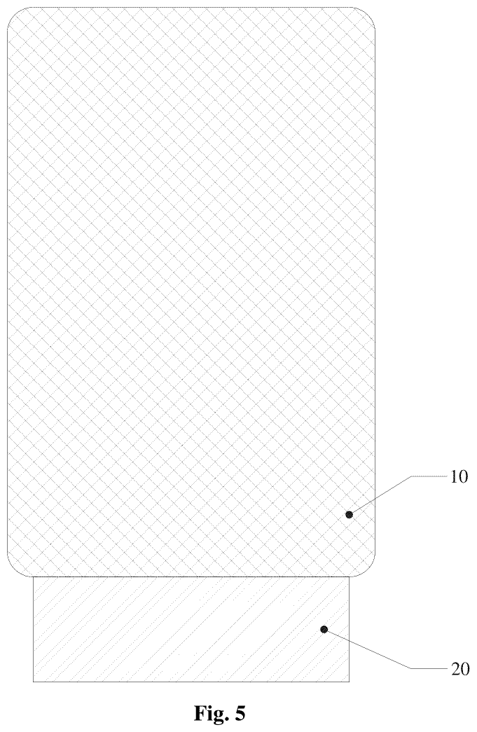

In some possible implementations, referring to FIG. 4, the display panel further includes an isolation structure 140 located on a side of the pixel definition layer 120 away from the substrate 111, and the isolation structure 140 extends into the contact hole 901, 902 to be in contact with the first wiring 1131. In this way, the isolation structure 140 may contact with the first wiring 1131 through the contact hole 901, 902 to achieve an electrical connection.

The pixel definition layer 120 in the contact hole 901, 902 covers the side surface of the organic layer 114 facing the contact hole 901, 902, and the organic layer 114 may be prevented from being in direct contact with the isolation structure 140 extending into the contact hole 901, 902, so that the water vapor absorbed by the organic layer 114 is prevented from affecting the manufacturing of the isolation structure 140 during a coating film molding process of the isolation structure 140, and a risk of a film layer abnormality of the isolation structure 140 is reduced.

In some possible implementations, referring to FIG. 5, the display panel includes a display region 10 and a contact region 20 located on a side of the display region 10, and the contact hole 901, 902 is located in the contact region 20. The display panel further includes a binding region, and the contact region 20 is located between the display region 10 and the binding region 20. The binding region is configured to bind a chip.

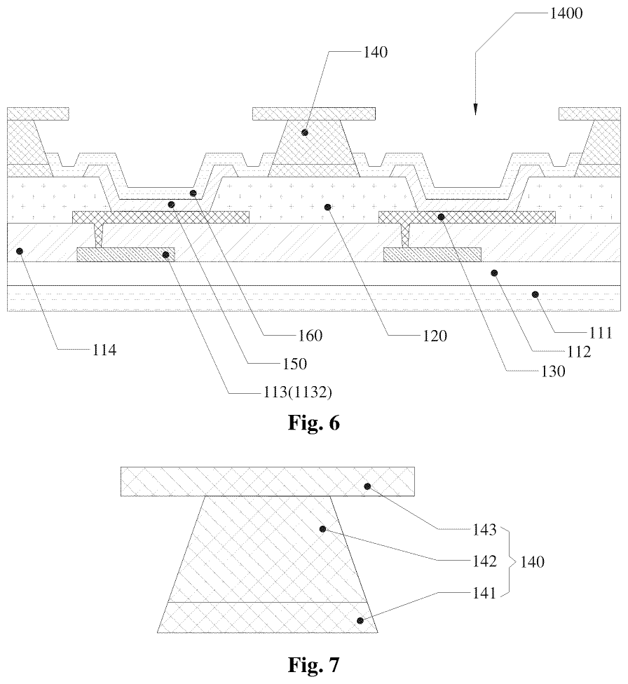

In some possible implementations, referring to FIG. 6, at least a part of the pixel definition layer 120 located in the display region 10 defines a pixel opening, at least a part of the isolation structure 140 located in the display region 10 defines an isolation opening, and an orthographic projection of the pixel opening on the substrate 111 is located within an orthographic projection of the isolation opening on the substrate 111. The technical solutions relating to the isolation structure 140 located in the display region 10 are recited in patent applications No. PCT/CN2023/134518, 202310759370.2, 202310740412.8, 202310707209.0, and 202311346196.5, contents of which are incorporated herein by reference.

Optionally, in some possible implementations, in the display region 10, the isolation structure 140 may include a support portion and a blocking portion located on a side of the support portion away from the substrate 111, and an orthographic projection of the support portion on the substrate 111 is located within an orthographic projection of the blocking portion on the substrate 111. That is, the isolation structure 140 located in the display region 10 has an undercut structure, so that an organic film layer between adjacent pixel openings can be better disconnected when other organic film layers are formed by subsequent evaporation.

In some possible implementations, referring to FIG. 7, the isolation structure 140 includes a first layer 141, a second layer 142, and a third layer 143 stacked along a direction away from the substrate 111. For example, a material of the first layer 141 includes molybdenum, a material of the second layer 142 includes aluminum, and a material of the third layer 143 includes titanium. Here, the support portion may be formed by the first layer 141 and the second layer 142, and the blocking portion may be formed by the third layer 143. In other implementations, the isolation structure 140 includes a second layer 142 and a third layer 143 stacked along a direction away from the substrate 111.

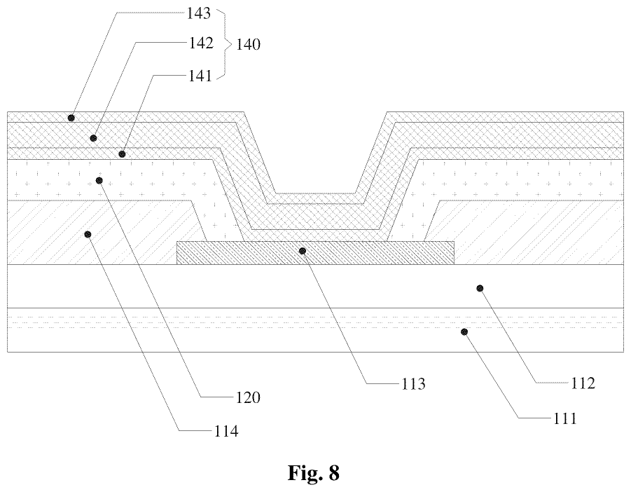

Referring to FIG. 8, at the contact hole 901, 902, after the isolation structure 140 extends into the contact hole 901, 902, the first layer 141 is electrically connected to the first wiring 1131.

In some possible implementations, still referring to FIG. 6, the display region 10 of the display panel further includes a first electrode 130, a light-emitting unit 150, and a second electrode 160.

The first electrode 130 is located on a side of the organic layer 114 away from the substrate 111, and a plurality of first electrodes 130 may be provided at intervals. At least a part of the first electrode 130 is located within the pixel opening, for example, one pixel opening exposes at least a part of one first electrode 130.

At least a part of the light-emitting unit 150 is located within the pixel opening and on a side of the first electrode 130 away from the substrate 111, and the light-emitting unit 150 is in contact with the first electrode 130.

At least a part of the second electrode 160 is located within the pixel opening and on a side of the light-emitting unit 150 away from the substrate 111, and the second electrode 160 is in contact with the light-emitting unit 150.

Under a condition that a potential difference exists between the first electrode 130 and the second electrode 160, the light-emitting unit 150 located between the first electrode 130 and the second electrode 160 is driven to emit light.

In some possible implementations, still referring to FIG. 6, at least a part of the second electrode 160 extends from inside the pixel opening to a side of the pixel definition layer 120 away from the substrate 111 to be in contact with the isolation structure 140.

In this way, second electrodes 160 corresponding to adjacent pixel openings may be electrically connected through the isolation structure 140 and connected to a common voltage (Vss) supply circuit, or respective second electrodes 160 may be connected to the common voltage supply circuit through the isolation structure 140 in relatively independent way.

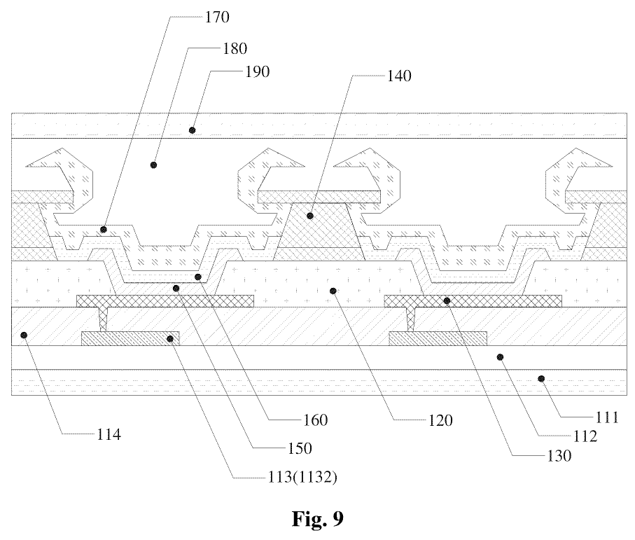

In some possible implementations, referring to FIG. 9, the display panel further includes a first encapsulation layer 170 located on a side of the second electrode 160 away from the substrate 111.

Optionally, the first encapsulation layer 170 may extend from inside the pixel opening to a side of the isolation structure 140 away from the substrate 111. The first encapsulation layer 170 corresponding to adjacent pixel openings may be disconnected on the side of the isolation structure 140 away from the substrate 111.

Further, in some possible implementations, the display panel further includes a second encapsulation layer 180 and a third encapsulation layer 190 stacked on a side of the first encapsulation layer 170 away from the substrate 111.

Optionally, materials of the first encapsulation layer 170 and the third encapsulation layer 190 include an inorganic material, and a material of the second encapsulation layer 180 includes an organic material. For example, the first encapsulation layer 170 and the third encapsulation layer 190 may be formed by Chemical Vapor Deposition (CVD), and the second encapsulation layer 180 may be formed by Ink-jet Printing (IJP).

Optionally, a gap may exist between a part of the first encapsulation layer 170 located on the side of the isolation structure 140 away from the substrate 111 and the isolation structure 140. The second encapsulation layer 180 may fill the gap.

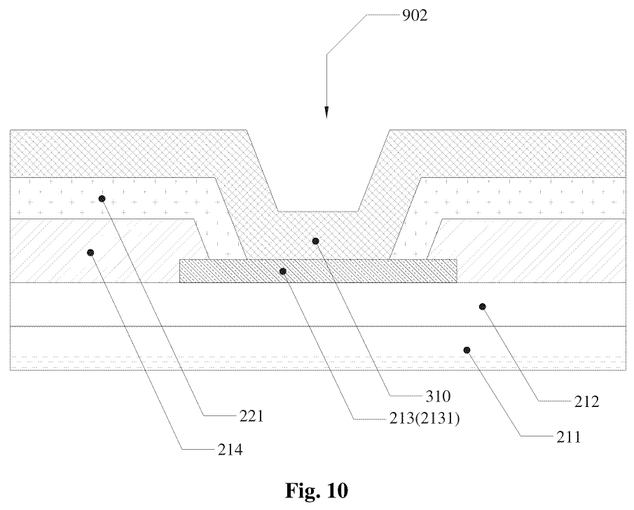

Referring to FIG. 10, FIG. 10 is a schematic view of a display panel according to the embodiment of the present application, and the display panel may include a substrate 211, a wiring layer 213, an organic layer 214, a first material layer 221, and an auxiliary electrode 310.

In the embodiment of the present application, a first wiring layer 213 is located on a side of the substrate 211, and one or more array functional film layers 212 may be included between the first wiring layer 213 and the substrate 211, for example, a buffer layer, a semiconductor layer, one or more other wiring layers 213, and one or more insulation layers may be included.

The wiring layer 213 includes a first wiring 2131. In addition to the first wiring 2131, the wiring layer 213 may further include other wirings, which is not repeated in the embodiment of the present application.

The organic layer 214 is located on a side of the wiring layer 213 away from the substrate 211 and includes a contact hole 901, 902 exposing at least a part of the first wiring 2131.

The first material layer 221 is located on a side of the organic layer 214 away from the substrate 211 and exposes at least a part of the first wiring 2131. That is, at the contact hole 901, 902, the first material layer 221 may cover an exposed part of the organic layer 214, and may still expose the first wiring 2131. Water absorbability of the first material layer 221 is lower than water absorbability of the organic layer 214.

Based on the above design, in the embodiment of the present application, the first material layer 221 in the contact hole 901, 902 covers a side surface of the organic layer 214 facing the contact hole 901, 902, and the organic layer 214 is prevented from being exposed at the contact hole 901, 902, so that a risk of the organic layer 214 being invaded by the water vapor at the contact hole 901, 902 can be reduced, and the yield of subsequent film layer manufacturing can be ensured.

In some possible implementations, a material of the first material layer 221 includes an inorganic material. In this way, the first material layer 221 provides a better water vapor isolation effect and better protect the organic layer 214 from the water vapor intrusion.

The auxiliary electrode 310 is located on a side of the first material layer 221 away from the substrate 211 and extends into the contact hole 901, 902 to be in contact with the first wiring 2131. In this way, the auxiliary electrode 310 may contact with the first wiring 2131 through the contact hole 901, 902 to achieve an electrical connection.

The first material layer 221 in the contact hole 901, 902 covers the side surface of the organic layer 214 facing the contact hole 901, 902, and the organic layer 214 may be prevented from being in direct contact with the auxiliary electrode 310 extending into the contact hole 901, 902, so that the water vapor absorbed by the organic layer 214 is prevented from affecting the manufacturing of the auxiliary electrode 310 during a coating film molding process of the auxiliary electrode 310, and a risk of a film layer abnormality of the auxiliary electrode 310 is reduced.

In some possible implementations, still referring to FIG. 5, the display panel includes a display region 10 and a contact region 20 located on a side of the display region 10, and the contact hole 901, 902 is located in the contact region 20.

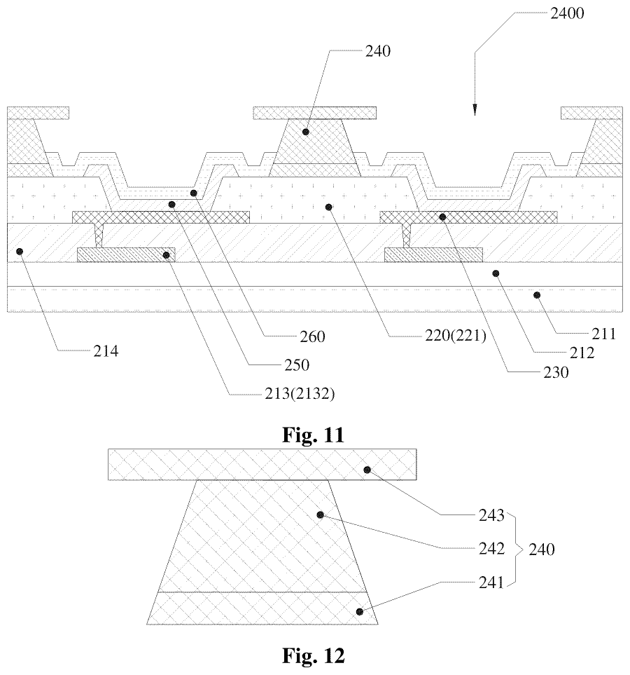

In some possible implementations, referring to FIG. 11, the display panel according to the embodiment of the present application further includes a pixel definition layer 220 located on a side of the organic layer 214 away from the substrate 211. The pixel definition layer 220 is provided in the same layer as the first material layer 221. The pixel definition layer 220 and the first material layer 221 are formed as an integrated structure, that is, the pixel definition layer 220 and the first material layer 221 are integrally formed and in contact with each other.

In some possible implementations, still referring to FIG. 11, the display panel according to the embodiment of the present application may further include an isolation structure 240 and a light-emitting unit 250.

The isolation structure 240 is located on a side of the first material layer 221 away from the substrate 221 and includes an isolation opening, and the light-emitting unit 250 is located in the isolation opening. The isolation structure 240 is reused as the auxiliary electrode 310.

Here, the technical solutions relating to the isolation structure 240 located in the display region 10 are recited in patent applications No. PCT/CN2023/134518, 202310759370.2, 202310740412.8, 202310707209.0, and 202311346196.5, contents of which are incorporated herein by reference.

Optionally, in some possible implementations, the isolation structure 240 may include a support portion and a blocking portion located on a side of the support portion away from the substrate 211, and an orthographic projection of the support portion on the substrate 211 is located within an orthographic projection of the blocking portion on the substrate 211. That is, the isolation structure 240 located in the display region 10 has an undercut structure, so that an organic film layer between adjacent pixel openings can be better disconnected when other organic film layers are formed by subsequent evaporation.

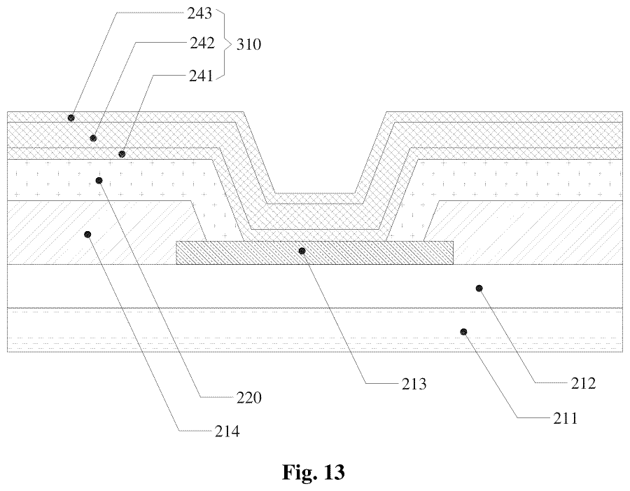

In some possible implementations, referring to FIG. 12, the isolation structure 240 includes a first layer 241, a second layer 242, and a third layer 243 stacked along a direction away from the substrate 211. For example, a material of the first layer 241 includes molybdenum, a material of the second layer 242 includes aluminum, and a material of the third layer 243 includes titanium. Here, the support portion may be formed by the first layer 241 and the second layer 242, and the blocking portion may be formed by the third layer 243. Accordingly, referring to FIG. 13, the auxiliary electrode 310 may also include the first layer 241, the second layer 242, and the third layer 243 stacked along the direction away from the substrate 211.

In some other possible implementations, the isolation structure 240 includes a second layer 242 and a third layer 243 stacked along a direction away from the substrate 211. For example, a material of the second layer 242 includes aluminum, and a material of the third layer 243 includes titanium. Here, the support portion may be formed by the second layer 242, and the blocking portion may be formed by the third layer 243. Accordingly, the auxiliary electrode 310 may also include the second layer 242 and the third layer 243 stacked along the direction away from the substrate 211.

In some possible implementations, referring to FIG. 11, the display panel further includes a first electrode 230 and a second electrode 260.

The first electrode 230 is located on a side of the organic layer 214 away from the substrate 211, and a plurality of first electrodes 230 may be provided at intervals. At least a part of the first electrode 230 is located within the pixel opening, for example, one pixel opening exposes at least a part of one first electrode 230.

At least a part of the light-emitting unit 250 is located within the pixel opening and on a side of the first electrode 230 away from the substrate 211, and the light-emitting unit 250 is in contact with the first electrode 230.

At least a part of the second electrode 260 is located within the pixel opening and on a side of the light-emitting unit 250 away from the substrate 211, and the second electrode 260 is in contact with the light-emitting unit 250.

Under a condition that a potential difference exists between the first electrode 230 and the second electrode 260, the light-emitting unit 250 located between the first electrode 230 and the second electrode 260 is driven to emit light.

In some possible implementations, still referring to FIG. 11, at least a part of the second electrode 260 extends from inside the pixel opening to a side of the pixel definition layer 220 away from the substrate 211 to be in contact with the isolation structure 240.

In this way, second electrodes 260 corresponding to adjacent pixel openings may be electrically connected through the isolation structure 240 and connected to a common voltage (Vss) supply circuit, or respective second electrodes 260 may be connected to the common voltage supply circuit through the isolation structure 240 in relatively independent way.

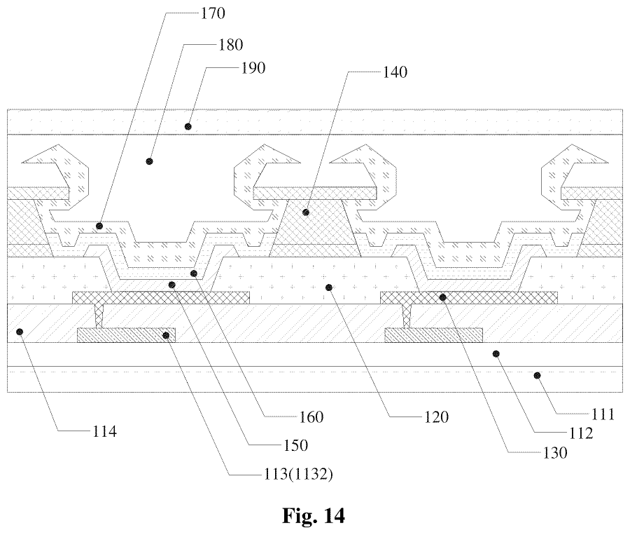

In some possible implementations, referring to FIG. 14, the display panel further includes a first encapsulation layer 270 located on a side of the second electrode 260 away from the substrate 211.

Optionally, the first encapsulation layer 270 may extend from inside the pixel opening to a side of the isolation structure 240 away from the substrate 211. The first encapsulation layer 270 corresponding to adjacent pixel openings may be disconnected on the side of the isolation structure 240 away from the substrate 211.

Further, in some possible implementations, the display panel further includes a second encapsulation layer 280 and a third encapsulation layer 290 stacked on a side of the first encapsulation layer 270 away from the substrate 211.

Optionally, materials of the first encapsulation layer 270 and the third encapsulation layer 290 include an inorganic material, and a material of the second encapsulation layer 280 includes an organic material. For example, the first encapsulation layer 270 and the third encapsulation layer 290 may be formed by Chemical Vapor Deposition (CVD), and the second encapsulation layer 280 may be formed by Ink-jet Printing (IJP).

Optionally, a gap may exist between a part of the first encapsulation layer 270 located on the side of the isolation structure 240 away from the substrate 211 and the isolation structure 240. The second encapsulation layer 280 may fill the gap.

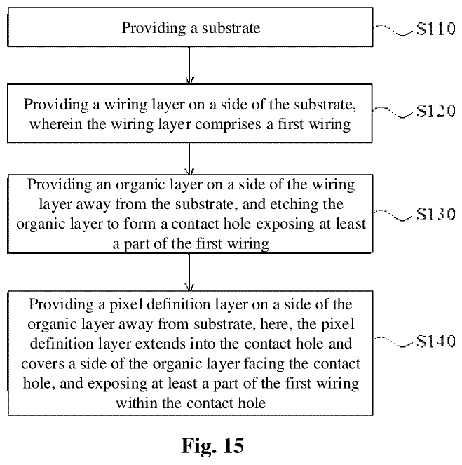

Referring to FIG. 15, the embodiment of the present application further provides a method for manufacturing a display panel, and the method may include the following steps.

Step S110, providing a substrate 111.

Step S120, providing a wiring layer 113 on a side of the substrate 111, here, the wiring layer 113 includes a first wiring 1131.

Step S130, providing an organic layer 114 on a side of the wiring layer 113 away from the substrate 111, here, the organic layer 114 includes a contact hole 901, 902 exposing at least a part of the first wiring 1131.

Step S140, providing a pixel definition layer 120 on a side of the organic layer 114 away from the substrate 111, here, the pixel definition layer 120 extends into the contact hole 901, 902 and covers a side of the organic layer 114 facing the contact hole 901, 902, and exposing at least a part of the first wiring 1131 within the contact hole 901, 902.

In some possible implementations, the wiring layer 113 further includes a second wiring 1132. The second wiring 1132 may be configured to provide a driving voltage for a first electrode 130.

In step S130, the organic layer 114 may be etched to form an electrode connection hole exposing at least a part of the second wiring 1132 and the contact hole 901, 902 exposing at least a part of the first wiring 1131. That is, the contact hole 901, 902 is formed while the organic layer 114 is etched to form the electrode connection hole.

Optionally, after step S130, the first electrode 130 may be formed on a side of the organic layer 114 away from the substrate 111, and the first electrode 130 extends into the electrode connection hole to be electrically connected to the second wiring 1132.

In some possible implementations, in step S140, the pixel definition layer 120 may be provided on the side of the organic layer 114 away from the substrate 111, and the pixel definition layer 120 is etched, so that the pixel definition layer 120 within the contact hole 901, 902 exposes at least a part of the first wiring 1131.

Then, an isolation structure 140 is provided on a side of the pixel definition layer 120 away from the substrate 111, and the isolation structure 140 extends into the contact hole 901, 902 to be in contact with the first wiring 1131. That is, the isolation structure 140 is provided after the pixel definition layer is etched to expose the first wiring 1131.

In some possible implementations, after the isolation structure 140 is provided on the side of the pixel definition layer 120 away from the substrate 111, an isolation layer may be etched to form an isolation opening.

Then, the pixel definition layer 120 may be etched to form a pixel opening in communication with the isolation opening. That is, the pixel definition layer 120 may be etched using the isolation structures 140 as a mask to form the pixel opening.

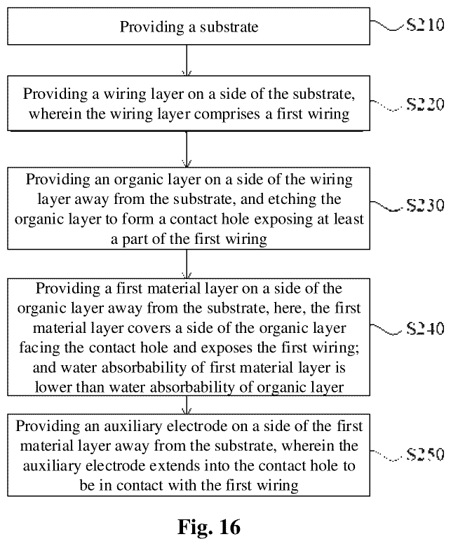

Referring to FIG. 16, the embodiment of the present application further provides a method for manufacturing a display panel, and the method may include the following steps.

Step S210, providing a substrate 211.

Step S220, providing a wiring layer 213 on a side of the substrate 211, here, the wiring layer 213 includes a first wiring 2131.

Step S230, providing an organic layer 214 on a side of the wiring layer 213 away from the substrate 211, and etching the organic layer 214 to form a contact hole 901, 902 exposing at least a part of the first wiring 2131.

Step S240, providing a first material layer 221 on a side of the organic layer 214 away from the substrate 211, here, the first material layer 221 covers a side of the organic layer 214 facing the contact hole 901, 902 and exposes at least a part of the first wiring 2131. Water absorbability of the first material layer 221 is lower than water absorbability of the organic layer 214.

Step S250, providing an auxiliary electrode 310 on a side of the first material layer 221 away from the substrate 211, here, the auxiliary electrode 310 extends into the contact hole 901, 902 to be in contact with the first wiring 2131.

In some possible implementations, the wiring layer 213 further includes a second wiring 2132. The second wiring 2132 may be configured to provide a driving voltage for a first electrode 230.

In step S230, the organic layer 214 may be etched to form an electrode connection hole exposing at least a part of the second wiring 2132 and the contact hole 901, 902 exposing at least a part of the first wiring 2131. That is, the contact hole 901, 902 is formed while the organic layer 214 is etched to form the electrode connection hole.

In some possible implementations, in step S240, the first material layer 221 may be provided on the side of the organic layer 214 away from the substrate 211, and the first material layer 221 is etched, so that the first material layer 221 within the contact hole 901, 902 exposes at least a part of the first wiring 2131.

In some possible implementations, in step S250, an isolation structure 240 may be provided on a side of the first material layer 221 away from the substrate 211, here, at least a part of the isolation structure 240 extends into the contact hole 901, 902 and is reused as the auxiliary electrode 310.

The present application further provides an electronic device including the display panel according to the present application, and the electronic device may include a device with a display function, such as a mobile phone, a tablet computer, a smart wearable device, a television, a notebook computer, a display device, and the like.

In summary, the present application provides the display panel, the method for manufacturing the display panel, and the electronic device, in the display panel having the isolation structure, the pixel definition layer in the contact hole covers the side surface of the organic layer facing the contact hole, and the organic layer is prevented from being exposed at the contact hole, so that the risk of the organic layer being invaded by water vapor at the contact hole can be reduced, and the yield of subsequent film layer manufacturing can be ensured.

The technical features of the above embodiments can be combined in any way, and in order to make the description clear, not all the possible combinations of the technical features in the above embodiments are described. However, as long as there is no contradiction among the combinations of these technical features, they should be considered as the scope that the specification recites.

The embodiments described above represent only a few implementations of the present invention and description thereof is relatively specific and detailed, but are not to be construed as limiting the patent scope of the present invention. It should be noted that a person skilled in the art could also make several changes and modifications without departing from the concept of the present invention, which falls within the scope of protection of this invention. Therefore, the protection scope of the present invention should be subject to the appended claims.

What is claimed is:

1. A display panel, comprising:
a substrate;
a wiring layer located on a side of the substrate, wherein the wiring layer comprises a first wiring;
an organic layer located on a side of the wiring layer away from the substrate, wherein the organic layer comprises a contact hole exposing at least a part of the first wiring; and
a pixel definition layer located on a side of the organic layer away from the substrate, wherein the pixel definition layer extends into the contact hole and covers a side of the organic layer facing the contact hole, and a part of the pixel definition layer is located within the contact hole and at least a part of the first wiring is exposed in the contact hole.

2. The display panel according to claim 1, wherein a material of the pixel definition layer comprises an inorganic material, the display panel further comprises a display region and a contact region located at a side of the display region, and the contact hole is disposed in the contact region.

3. The display panel according to claim 1, wherein the display panel further comprises an isolation structure located on a side of the organic layer away from the substrate, and the isolation structure extends into the contact hole to be in contact with the first wiring.

4. The display panel according to claim 3, wherein the display panel comprises a display region, at least a part of the pixel definition layer located in the display region defines a pixel opening, the isolation structure is provided on a side of the pixel definition layer away from the substrate, at least a part of the isolation structure located in the display region defines an isolation opening, and an orthographic projection of the pixel opening on the substrate is located within an orthographic projection of the isolation opening on the substrate.

5. The display panel according to claim 4, wherein the organic layer comprises a planarization layer;
the display region of the display panel further comprises:
a first electrode located on a side of the planarization layer away from the substrate, wherein at least a part of the first electrode is located within the pixel opening;
a light-emitting unit at least partially located within the pixel opening and located on a side of the first electrode away from the substrate, wherein the light-emitting unit is in contact with the first electrode; and
a second electrode at least partially located within the pixel opening and located on a side of the light-emitting unit away from the substrate, wherein the second electrode is in contact with the light-emitting unit.

6. The display panel according to claim 5, wherein the second electrode is in contact with the isolation structure.

7. A display panel, comprising:
a substrate;
a wiring layer located on a side of the substrate, wherein the wiring layer comprises a first wiring;
an organic layer located on a side of the wiring layer away from the substrate, wherein the organic layer comprises a contact hole exposing at least a part of the first wiring; and
a first material layer, covering a side of the organic layer facing the contact hole and exposing the first wiring; wherein water absorbability of the first material layer is lower than water absorbability of the organic layer; and
an auxiliary electrode located on a side of the first material layer away from the substrate and extending into the contact hole to be in contact with the first wiring.

8. The display panel according to claim 7, wherein the display panel comprises a display region and a contact region located on a side of the display region, and the contact hole is located in the contact region; and
the display panel further comprises a binding region, and the contact region is located between the display region and the binding region.

9. The display panel according to claim 7, wherein a material of the first material layer comprises an inorganic material.

10. The display panel according to claim 7, wherein the display panel further comprises a pixel definition layer located on a side of the organic layer away from the substrate, and the first material layer is provided in the same layer as the pixel definition layer.

11. The display panel according to claim 10, wherein the first material layer and the pixel definition layer are formed as an integrated structure.

12. The display panel according to claim 7, wherein the display panel further comprises an isolation structure and a light-emitting unit, and the isolation structure is located on a side of the first material layer away from the substrate and is provided with an isolation opening; the light-emitting unit is located in the isolation opening; and the isolation structure is reused as the auxiliary electrode.

13. The display panel according to claim 12, wherein the isolation structure comprises a first layer, a second layer, and a third layer stacked along a direction away from the substrate; or the isolation structure comprises a second layer and a third layer stacked along a direction away from the substrate.

14. The display panel according to claim 13, wherein a material of the second layer comprises aluminum, and a material of the third layer comprises titanium;
a material of the first layer comprises molybdenum.

15. A method for manufacturing a display panel, wherein the method comprises:
providing a substrate;
providing a wiring layer on a side of the substrate, wherein the wiring layer comprises a first wiring;
providing an organic layer on a side of the wiring layer away from the substrate, and etching the organic layer to form a contact hole exposing at least a part of the first wiring; and
providing a pixel definition layer on a side of the organic layer away from the substrate, wherein the pixel definition layer extends into the contact hole and covers a side of the organic layer facing the contact hole, and exposing at least a part of the first wiring within the contact hole.

16. The method according to claim 15, wherein the wiring layer further comprises a second wiring; and forming the contact hole on the organic layer comprises:
etching the organic layer to form an electrode connection hole exposing at least a part of the second wiring and the contact hole exposing at least a part of the first wiring;
before providing the pixel definition layer on the side of the organic layer away from the substrate, the method further comprises:
forming a first electrode on a side of the organic layer away from the substrate, wherein the first electrode extends into the electrode connection hole to be electrically connected to the second wiring.

17. The method according to claim 15, wherein after providing the pixel definition layer on the side of the organic layer away from the substrate, the method further comprises:
providing an isolation structure on a side of the organic layer away from the substrate, wherein the isolation structure extends into the contact hole to be in contact with the first wiring.

18. A method for manufacturing a display panel, wherein the method comprises:
providing a substrate;
providing a wiring layer on a side of the substrate, wherein the wiring layer comprises a first wiring;
providing an organic layer on a side of the wiring layer away from the substrate, and etching the organic layer to form a contact hole exposing at least a part of the first wiring;
providing a first material layer on a side of the organic layer away from the substrate, wherein the first material layer covers a side of the organic layer facing the contact hole and exposes the first wiring; and water absorbability of the first material layer is lower than water absorbability of the organic layer; and
providing an auxiliary electrode on a side of the first material layer away from the substrate, wherein the auxiliary electrode extends into the contact hole to be in contact with the first wiring.

19. The method according to claim 18, wherein providing the auxiliary electrode on the side of the first material layer away from the substrate comprises:
providing an isolation structure on a side of the first material layer away from the substrate; wherein the isolation structure comprises an isolation opening and is reused as the auxiliary electrode.

20. An electronic device, comprising the display panel according to claim 1.
